(19) United States
(12) Patent Application Publication
(10) Pub. No.: US 2025/0202624 A1
(43) Pub. Date: Jun. 19, 2025

(54) TECHNIQUES FOR INTERLEAVED LOW-DENSITY PARITY-CHECK MODULATIONS

(71) Applicant: Lenovo (United States) Inc., Morrisville, NC (US)

(72) Inventors: Abir Ben Hadj Fredj, Frankfurt (DE); Razvan-Andrei Stoica, Witten (DE); Karthikeyan Ganesan, Nauheim (DE); Ali Ramadan Ali, Kraiburg am Inn (DE)

(21) Appl. No.: 19/067,630

(22) Filed: Feb. 28, 2025

(51) Int. Cl. H04L 1/00

(52) U.S. Cl. CPC H04L 1/0071; H04L 1/0041; H04L 1/0045

(57) ABSTRACT

Various aspects of the present disclosure relate to techniques for interleaved low-density parity-check (LDPC) modulations. An apparatus is configured to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled Quadrature Amplitude Modulation (QAM) on the stream of re-ordered encoded bits to generate one or more modulation symbols, and transmit the one or more modulation symbols.

### TECHNICAL FIELD

The present disclosure relates to wireless communications, and more specifically to techniques for interleaved low-density parity-check (LDPC) modulations.

### BACKGROUND

A wireless communications system may include one or multiple network communication devices, which may be otherwise known as network equipment (NE), supporting wireless communications for one or multiple user communication devices, which may be otherwise known as user equipment (UE), or other suitable terminology. The wireless communications system may support wireless communications with one or multiple user communication devices by utilizing resources of the wireless communication system (e.g., time resources (e.g., symbols, slots, subframes, frames, or the like) or frequency resources (e.g., subcarriers, carriers, or the like)). Additionally, the wireless communications system may support wireless communications across various radio access technologies including third generation (3G) radio access technology, fourth generation (4G) radio access technology, fifth generation (5G) radio access technology, among other suitable radio access technologies beyond 5G (e.g., sixth generation (6G)).

### SUMMARY

An article “a” before an element is unrestricted and understood to refer to “at least one” of those elements or “one or more” of those elements. The terms “a,” “at least one,” “one or more,” and “at least one of one or more” may be interchangeable. As used herein, including in the claims, “or” as used in a list of items (e.g., a list of items prefaced by a phrase such as “at least one of” or “one or more of” or “one or both of) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” Further, as used herein, including in the claims, a “set” may include one or more elements.

A UE and/or an NE for wireless communication is described. The UE and/or NE may be configured to, capable of, or operable to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled Quadrature Amplitude Modulation (QAM) on the stream of re-ordered encoded bits to generate one or more modulation symbols, and transmit the one or more modulation symbols.

A processor for wireless communication is described. The processor may be configured to, capable of, or operable to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled QAM on the stream of re-ordered encoded bits to generate one or more modulation symbols, and transmit the one or more modulation symbols.

A method for wireless communication performed by a UE and/or an NE is described. The method may be configured to, capable of, or operable to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled QAM on the stream of re-ordered encoded bits to generate one or more modulation symbols, and transmit the one or more modulation symbols.

A UE and/or an NE for wireless communication is described. The UE and/or an NE may be configured to, capable of, or operable to detect one or more constellation symbols associated with a stream of LDPC encoded bits, demodulate the one or more constellation symbols to generate one or more log-likelihood ratios, and decode the encoded bits by providing the log-likelihood ratios to an LDPC decoder to generate a stream of decoded bits.

A processor for wireless communication is described. The processor may be configured to, capable of, or operable to detect one or more constellation symbols associated with a stream of LDPC encoded bits, demodulate the one or more constellation symbols to generate one or more log-likelihood ratios, and decode the encoded bits by providing the log-likelihood ratios to an LDPC decoder to generate a stream of decoded bits.

A method for wireless communication performed by a UE and/or an NE is described. The method may be configured to, capable of, or operable to detect one or more constellation symbols associated with a stream of LDPC encoded bits, demodulate the one or more constellation symbols to generate one or more log-likelihood ratios, and decode the encoded bits by providing the log-likelihood ratios to an LDPC decoder to generate a stream of decoded bits.

### BRIEF DESCRIPTION OF THE DRAWINGS

FIG. 1 illustrates an example of a wireless communications system, in accordance with aspects of the present disclosure.

FIG. 2 illustrates an example transmission chain of interleaved LDPC-coded modulation, in accordance with aspects of the present disclosure.

FIG. 3 illustrates an example receiver chain of interleaved LDPC-coded modulation, in accordance with aspects of the present disclosure.

FIG. 4 illustrates an example of AI-assisted Interleaved coded modulation, in accordance with aspects of the present disclosure.

FIG. 5 illustrates a flowchart of a method performed by a UE or an NE in accordance with aspects of the present disclosure.

FIG. 6 illustrates an example of a UE, in accordance with aspects of the present disclosure.

FIG. 7 illustrates an example of a processor, in accordance with aspects of the present disclosure.

FIG. 8 illustrates an example of an NE, in accordance with aspects of the present disclosure.

FIG. 9 illustrates a flowchart of a method performed by a UE or an NE, in accordance with aspects of the present disclosure.

FIG. 10 illustrates a flowchart of a method performed by a UE or an NE, in accordance with aspects of the present disclosure.

### DETAILED DESCRIPTION

Generally, the present disclosure describes systems, methods, and apparatuses for techniques for interleaved LDPC modulations. In certain embodiments, the methods may be performed using computer-executable code embedded on a computer-readable medium. In certain embodiments, an apparatus or system may include a computer-readable medium containing computer-readable code which, when executed by a processor, causes the apparatus or system to perform at least a portion of the below described solutions.

UEs and/or NEs may be configured with 6G capabilities, such as AI and sensing, which previous generations of wireless communications did not support. The usage scenarios for these devices may include immersive communication, hyper-reliable and low-latency communication, ubiquitous connectivity, massive communication, AI, as well as integrated sensing and communication. To support these use cases, stringent target requirements have been defined in terms of spectral efficiency, energy efficiency, latency, and reliability.

Channel coding and modulation schemes are fundamental building blocks in wireless communication systems. High order modulations (e.g., super quadrature amplitude modulation (QAM)), for example, 1024-QAM and 4096-QAM) present an attractive and promising way to increase spectral efficiency. While other solutions, like MU-MIMO and SU-MIMO, exist for high spectral efficiency, they are limited in mobility scenarios and other situations where the channel rank is limited. High order modulations serve as complementary solutions to maintain high spectral efficiencies in these scenarios. Conventional coherent transmission is based on QAM, which uses a combination of phase and amplitude to encode bits of data.

Each point in a constellation (e.g., a diagram that represents the modulation scheme used to encode data onto a carrier signal) is a unique combination of phase and amplitude, with phase represented by the angle and amplitude by the distance from the center of the diagram. Super QAM modulations result in a decreased minimum Euclidean distance (MSD) of the constellation, which might impact the symbol detection and decoding performance especially in fading channels. In such scenarios, bit-to-symbol mapping and enhanced LDPC error correction capabilities could be targeted to compensate for the reduced MSD of super QAMs and the impacts of fading channels on the received signal.

This disclosure presents solutions and procedures that enable the enhancement of quasi-cyclic LDPC (QC-LDPC) codes correction capabilities by further protecting the LDPC variable nodes associated with high degrees using a bit re-ordering (interleaver) mechanism between the LDPC encoder and the super QAM modulation. The added block, called an interleaver, ensures that variable nodes with high degrees (e.g., degrees greater than or that otherwise satisfy a threshold) are transmitted as the most significant bits (MSBs) of one or more constellation symbols and that variable nodes with low degrees (e.g., degrees less than or that otherwise satisfy a threshold) are transmitted as the least significant bits (LSBs) of one or more constellation symbols. This ensures that the variable nodes impacting the iterative decoder performance and error correction capabilities of LDPC codes are further protected. This scheme may be combined with a Gray-Labeled QAM, which further enhances the detection and decidability of the bit stream at the decoder.

By enabling the enhancement of QC-LDPC codes correction capabilities, the NE and/or the UE may experience improved spectral efficiency, improved energy efficiency, improved latency, and improved reliability. In this manner, battery life and operational efficiencies in NE and/or the UE devices can be enhanced.

Aspects of the present disclosure are described in the context of a wireless communications system. Note that one or more aspects from different solutions may be combined.

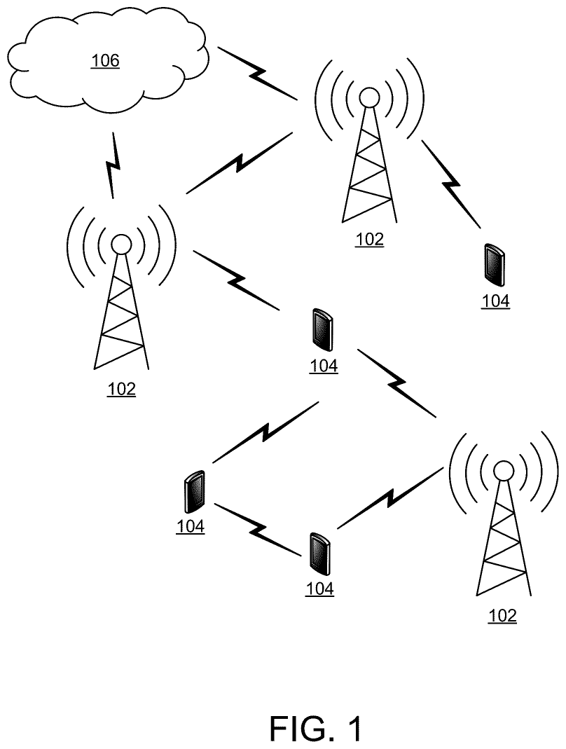

FIG. 1 illustrates an example of a wireless communications system 100 in accordance with aspects of the present disclosure. The wireless communications system 100 may include one or more NE 102, one or more UE 104, and a core network (CN) 106. The wireless communications system 100 may support various radio access technologies. In some implementations, the wireless communications system 100 may be a 4G network, such as a Long-Term Evolution (LTE) network or an LTE-Advanced (LTE-A) network. In some other implementations, the wireless communications system 100 may be a New Radio (NR) network, such as a 5G network, a 5G-Advanced (5G-A) network, or a 5G ultrawideband (5G-UWB) network. In other implementations, the wireless communications system 100 may be a combination of a 4G network and a 5G network, or other suitable radio access technology including Institute of Electrical and Electronics Engineers (IEEE) 802.11 (Wi-Fi), IEEE 802.16 (WiMAX), IEEE 802.20. The wireless communications system 100 may support radio access technologies beyond 5G, for example, 6G. Additionally, the wireless communications system 100 may support technologies, such as time division multiple access (TDMA), frequency division multiple access (FDMA), or code division multiple access (CDMA), etc.

The one or more NE 102 may be dispersed throughout a geographic region to form the wireless communications system 100. One or more of the NE 102 described herein may be or include or may be referred to as a network node, a base station, a network element, a network function, a network entity, a radio access network (RAN), a NodeB, an eNodeB (eNB), a next-generation NodeB (gNB), or other suitable terminology. An NE 102 and a UE 104 may communicate via a communication link, which may be a wireless or wired connection. For example, an NE 102 and a UE 104 may perform wireless communication (e.g., receive signaling, transmit signaling) over a Uu interface.

An NE 102 may provide a geographic coverage area for which the NE 102 may support services for one or more UEs 104 within the geographic coverage area. For example, an NE 102 and a UE 104 may support wireless communication of signals related to services (e.g., voice, video, packet data, messaging, broadcast, etc.) according to one or multiple radio access technologies. In some implementations, an NE 102 may be moveable, for example, a satellite associated with a non-terrestrial network (NTN). In some implementations, different geographic coverage areas associated with the same or different radio access technologies may overlap, but the different geographic coverage areas may be associated with different NE 102.

The one or more UE 104 may be dispersed throughout a geographic region of the wireless communications system 100. A UE 104 may include or may be referred to as a remote unit, a mobile device, a wireless device, a remote device, a subscriber device, a transmitter device, a receiver device, or some other suitable terminology. In some implementations, the UE 104 may be referred to as a unit, a station, a terminal, or a client, among other examples. Additionally, or alternatively, the UE 104 may be referred to as an Internet-of-Things (IoT) device, an Internet-of-Everything (IoE) device, or machine-type communication (MTC) device, among other examples.

A UE 104 may be able to support wireless communication directly with other UEs 104 over a communication link. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link may be referred to as a sidelink. For example, a UE 104 may support wireless communication directly with another UE 104 over a PC5 interface.

An NE 102 may support communications with the CN 106, or with another NE 102, or both. For example, an NE 102 may interface with other NE 102 or the CN 106 through one or more backhaul links (e.g., S1, N2, N2, or network interface). In some implementations, the NE 102 may communicate with each other directly. In some other implementations, the NE 102 may communicate with each other or indirectly (e.g., via the CN 106). In some implementations, one or more NE 102 may include subcomponents, such as an access network entity, which may be an example of an access node controller (ANC). An ANC may communicate with the one or more UEs 104 through one or more other access network transmission entities, which may be referred to as a radio heads, smart radio heads, or transmission-reception points (TRPs).

The CN 106 may support user authentication, access authorization, tracking, connectivity, and other access, routing, or mobility functions. The CN 106 may be an evolved packet core (EPC), or a 5G core (5GC), which may include a control plane entity that manages access and mobility (e.g., a mobility management entity (MME), an access and mobility management functions (AMF)) and a user plane entity that routes packets or interconnects to external networks (e.g., a serving gateway (S-GW), a Packet Data Network (PDN) gateway (P-GW), or a user plane function (UPF)). In some implementations, the control plane entity may manage non-access stratum (NAS) functions, such as mobility, authentication, and bearer management (e.g., data bearers, signal bearers, etc.) for the one or more UEs 104 served by the one or more NE 102 associated with the CN 106.

The CN 106 may communicate with a packet data network over one or more backhaul links (e.g., via an S1, N2, N2, or another network interface). The packet data network may include an application server. In some implementations, one or more UEs 104 may communicate with the application server. A UE 104 may establish a session (e.g., a protocol data unit (PDU) session, or a PDN connection, or the like) with the CN 106 via an NE 102. The CN 106 may route traffic (e.g., control information, data, and the like) between the UE 104 and the application server using the established session (e.g., the established PDU session). The PDU session may be an example of a logical connection between the UE 104 and the CN 106 (e.g., one or more network functions of the CN 106).

In the wireless communications system 100, the NEs 102 and the UEs 104 may use resources of the wireless communications system 100 (e.g., time resources (e.g., symbols, slots, subframes, frames, or the like) or frequency resources (e.g., subcarriers, carriers)) to perform various operations (e.g., wireless communications). In some implementations, the NEs 102 and the UEs 104 may support different resource structures. For example, the NEs 102 and the UEs 104 may support different frame structures. In some implementations, such as in 4G, the NEs 102 and the UEs 104 may support a single frame structure. In some other implementations, such as in 5G and among other suitable radio access technologies, the NEs 102 and the UEs 104 may support various frame structures (i.e., multiple frame structures). The NEs 102 and the UEs 104 may support various frame structures based on one or more numerologies.

One or more numerologies may be supported in the wireless communications system 100, and a numerology may include a subcarrier spacing and a cyclic prefix. A first numerology (e.g., μ=0) may be associated with a first subcarrier spacing (e.g., 15 kHz) and a normal cyclic prefix. In some implementations, the first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=4) may be associated with a fifth subcarrier spacing (e.g., 240 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally or alternatively, a time interval of a resource (e.g., a communication resource) may be organized according to slots. For example, a subframe may include a number (e.g., quantity) of slots. The number of slots in each subframe may also depend on the one or more numerologies supported in the wireless communications system 100. For instance, the first, second, third, fourth, and fifth numerologies (i.e., μ=0, μ=1, μ=2, μ=3, μ=4) associated with respective subcarrier spacings of 15 kHz, 30 kHz, 60 kHz, 120 kHz, and 240 kHz may utilize a single slot per subframe, two slots per subframe, four slots per subframe, eight slots per subframe, and 16 slots per subframe, respectively. Each slot may include a number (e.g., quantity) of symbols (e.g., orthogonal frequency domain multiplexing (OFDM) symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communications system 100, an electromagnetic (EM) spectrum may be split, based on frequency or wavelength, into various classes, frequency bands, frequency channels, etc. By way of example, the wireless communications system 100 may support one or multiple operating frequency bands, such as frequency range designations FR1 (410 MHz-7.125 GHZ), FR2 (24.25 GHZ-52.6 GHZ), FR3 (7.125 GHz-24.25 GHZ), FR4 (52.6 GHZ-114.25 GHZ), FR4a or FR4-1 (52.6 GHz-71 GHZ), and FR5 (114.25 GHZ-300 GHz). In some implementations, the NEs 102 and the UEs 104 may perform wireless communications over one or more of the operating frequency bands. In some implementations, FR1 may be used by the NEs 102 and the UEs 104, among other equipment or devices for cellular communications traffic (e.g., control information, data). In some implementations, FR2 may be used by the NEs 102 and the UEs 104, among other equipment or devices for short-range, high data rate capabilities.

FR1 may be associated with one or multiple numerologies (e.g., at least three numerologies). For example, FR1 may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

In certain cases, there are at least fifteen capabilities for 6G technology, nine of which will be enhanced from existing 5G capabilities, including security and resilience, latency, mobility, connection density, peak data rate, and spectrum efficiency. Some of the new capabilities include:

Coverage: The ability to provide access to communication services for users in a desired service area. Previously coverage was not built into standards but a function of the regulatory regime of different countries.

Sustainability: 6G and devices such as smartphones and tablets will minimize greenhouse gas emissions and the other environmental impacts of their life cycle.

Sensing-related capabilities: This refers to the ability to provide functionality through the radio signal, including object detection, localization, imaging, and mapping.

Applicable artificial intelligence (AI)-related capabilities: AI-based capabilities can support applications, including distributed data processing, distributed learning, computing, and model execution and inference. They can also optimize and automate existing network functions.

Interoperability: This refers to the radio interface being based on member inclusivity and transparency.

Positioning: The ability to calculate the approximate position of connected devices. The positioning accuracy is defined as the difference between the calculated horizontal/vertical position and the actual horizontal/vertical position of a device.

The overall capabilities for 6G technology include:

Peak data rate—Maximum achievable data rate under ideal conditions per device.

User experienced data rate—Achievable data rate that is available ubiquitously across the coverage area to a mobile device.

Spectrum efficiency—Spectrum efficiency refers to average data throughput per unit of spectrum resource and per cell.

Area traffic capacity—Total traffic throughput served per geographic area. The research target of area traffic capacity would be greater than that of IMT-2020. Values of 30 Mbit/s/m² and 50 Mbit/s/m² are given as possible examples, while other values greater than these examples may also be explored and considered accordingly.

Connection Density—Total number of connected and/or accessible devices per unit area. The research target of connection density could be 10⁶-10⁸ devices/km².

Mobility—Maximum speed, at which a defined QoS and seamless transfer between radio nodes which may belong to different layers and/or radio access technologies (multi-layer/multi-RAT) can be achieved.

Latency—Latency over the air interface refers to the contribution by the radio network to the time from when the source sends a packet of a certain size to when the destination receives it.

Reliability—Reliability over the air interface relates to the capability of successfully transmitting a predefined amount of data within a predetermined time duration with a given probability.

Coverage—Coverage refers to the ability to provide access to communication services for users in a desired service area. In the context of this capability, coverage is defined as the cell edge distance of a single cell through link budget analysis.

Positioning—Positioning is the ability to calculate the approximate position of connected devices. Positioning accuracy is defined as the difference between the calculated horizontal/vertical position and the actual horizontal/vertical position of a device.

Sensing—related capabilities-Sensing-related capabilities refer to the ability to provide functionalities in the radio interface including range/velocity/angle estimation, object detection, localization, imaging, mapping, etc. These capabilities could be measured in terms of accuracy, resolution, detection rate, false alarm rate, etc.

Applicable AI—related capabilities-Applicable AI-related capabilities refer to the ability to provide certain functionalities to support AI enabled applications. These functionalities include distributed data processing, distributed learning, AI computing, AI model execution, and AI model inference, etc.

Security and resilience—Security refers to preservation of confidentiality, integrity, and availability of information, such as user data and signaling, and protection of networks, devices, and systems against cyberattacks such as hacking, distributed denial of service, man in the middle attacks, etc. Resilience refers to capabilities of the networks and systems to continue operating correctly during and after a natural or man-made disturbance, such as the loss of primary source of power, etc.

Sustainability—Sustainability, or more specifically environmental sustainability, refers to the ability of both the network and devices to minimize greenhouse gas emissions and other environmental impacts throughout their life cycle. Important factors include improving energy efficiency, minimizing energy consumption and the use of resources, for example by optimizing for equipment longevity, repair, reuse and recycling. Energy efficiency is a quantifiable metric of sustainability. It refers to the quantity of information bits transmitted or received, per unit of energy consumption (in bit/Joule). Energy efficiency is expected to be improved appropriately with the capacity increase in order to minimize overall power consumption.

Interoperability—Interoperability refers to the radio interface being based on member-inclusivity and transparency, so as to enable functionality (ies) between different entities of the system.

In some cases, LDPC codes have excellent performance with iterative decoding that is close to the Shannon limit over Additive White Gaussian Noise (AWGN) channels. QC-LDPC codes have been adopted for data channels in 5G networks due to their low complexity implementation and near Shannon limit performance.

In some cases, an (n,k)—LDPC code is a linear block code for which the parity-check matrix H has a low density of 1 s. H is an (n−k)×n parity-check matrix whose rows are vectors {hᵢ}. The parity-check matrix performs m=n−k separate parity-checks on a received word. A regular LDPC code is a linear block code whose parity-check matrix H contains exactly w_{c} 1's in each column and exactly wᵣ=w_{c}(n/m) 1's in each row, where w_{c}<<m (and equivalently wᵣ<<m). The code rate

$$R = \frac{k}{n}$$

is related to these parameters via (R=1−w_{c}/wᵣ) which assumes H is full rank. If H is low density, but the number of 1's in each column or row is not constant, then the code is an irregular LDPC code. It is easiest to see the sense in which an LDPC code is regular or irregular through its graphical representation.

5G NR QC-LDPC are codes that can be put into quasi-cyclic form. Its parity check matrix can be put into the form of a block matrix consisting of either circulant permutation sub-matrices or the zero sub-matrix. Such codes are often constructed by lifting certain protographs into such block matrices. Their simple structure makes them useful for several wireless communication standards.

LDPC codes can be shown by a bipartite graph called a Tanner graph. The Tanner graph is composed of two sets of nodes, variable nodes, and check nodes. Each variable node and check node corresponds to the number of codeword symbols and parity symbols, respectively. If a variable node is constrained by a check node, there is an edge connecting these two nodes. A cycle (or a loop) of length υ in a Tanner graph is a path comprising υ edges which closes back in itself. The girth g of the code is the length of the shortest cycle in its Tanner graph, and it is a crucial parameter. The shortest possible cycle in a Tanner graph is clearly a length-4 cycle, and such cycles manifest themselves in the parity check matrix as four 1's that lie on the corners of a submatrix of H. In some cases, cycles are of interest because they degrade the performance of the iterative decoding algorithm used for LDPC codes.

In one embodiment, in Extrinsic Message Degree (EMD), for a given cycle [symbol] in the LDPC code graph, let [symbol] the set of the variable nodes in [symbol] and C( [symbol] ) is the set of the check node neighbors of [symbol] . The set C( [symbol] ) can be divided into three disjoint subsets:

C^{cyc}( [symbol] ): subset of C( [symbol] ) belonging to the cycle [symbol] . Each node of C^{cyc}( [symbol] ) is at least double connected to the set [symbol] .

C^{cut}( [symbol] ): subset of C( [symbol] ) that are not in the cycle [symbol] , But are at least double connected to the set [symbol] , and

C^{ext}( [symbol] ): subset of C( [symbol] ) singly connected to the set [symbol] .

This definition leads to another related to the edges.

In another embodiment, in EMD, for a given cycle [symbol] in the LDPC code graph, let [symbol] the set of the variable nodes in [symbol] , let E( [symbol] ) be the set of edges incident to [symbol] . The set E( [symbol] ) can be divided into three disjoint subsets:

E^{cyc}( [symbol] ): subset of cycle edges in E( [symbol] ) incident to check nodes in C^{cyc}( [symbol] ).

E^{cut}( [symbol] ): subset of cut edges in E( [symbol] ) incident to check nodes in C^{cut}( [symbol] ), and

E^{ext}( [symbol] ): subset of extrinsic edges in E( [symbol] ) incident to check nodes in C^{ext}( [symbol] ).

In another embodiment, the EMD of a given cycle [symbol] in the LDPC code graph, denoted EMD( [symbol] ), is EMD( [symbol] )=|E^{ext}( [symbol] )| where |E^{ext}( [symbol] )| is the cardinality of E^{ext}( [symbol] ) i.e. the number of extrinsic edges of [symbol] .

In some cases, if a given cycle in LDPC code graph has low EMD, then its communication with the rest of the graph is limited. This limits the amount of new evidence about values of variable nodes in the cycle that could be collected from the rest of the graph. In the extreme case, when the EMD of the cycle is zero, variable nodes in the cycle are isolated from the rest of the graph and the cycle is a stopping set.

In certain cases, it is not trivial to find the EMD of the cycle in the graph since it takes additional steps to determine if the edge is extrinsic edge or cut edge. If this difference is neglected and if both extrinsic and cut edges are accounted for in the cycle metric, a simplified version of the EMD metric can be determined.

In one embodiment, the approximated cycle EMD (ACE) of a given cycle [symbol] in the LDPC code graph, denoted ACE( [symbol] ) is ACE( [symbol] )=|E^{ext}( [symbol] )|+|E^{cut}( [symbol] )|. It is easy to calculate ACE( [symbol] ) as ACE( [symbol] )= [symbol] (d(v)−2), where d(v) is the degree of variable node v.

The bit sequence input for a given code block to channel coding is denoted by c₀, c₁, c₂, c₃, . . . , c_{K-1}, where K is the number of bits that could be calculated at the output of the code block (CB) segmentation and cyclic redundancy check (CRC) attachment.

After encoding, the bits are denoted by d₀, d₁, d₂, . . . , d_{N-1}, where N=66Z_{c} for LDPC base graph 1 and N=50Z_{c} for LDPC base graph 2, and the value of the lifting size Z_{c} e.g., as provided in TS 38.212 section 5 (incorporated herein by reference).

In some cases, an LDPC encoder is based on the determination of a parity check matrix H. Parity check matrices could be determined based on chosen base graphs and lifting sizes Z_{c}. For LDPC base graph 1, a matrix of H_{BG} has 46 rows with row indices i=0,1,2, . . . , 45 and 68 columns with column indices j=0,1,2, . . . , 67. For LDPC base graph 2, a matrix of H_{BG} has 42 rows with row indices i=0,1,2, . . . , 41 and 52 columns with column indices j=0,1,2, . . . , 51. The elements in H_{BG} with row and column indices given in TS 38.212 Table 5.3.2-2 (for LDPC base graph 1) and TS 38.212 Table 5.3.2-3 (for LDPC base graph 2) are of value 1, and all other elements in H_{BG} are of value 0.

Once the parity check matrix is calculated, the N+2Z_{c}−K parity bits w=[w₀, w₁, w₂, . . . , w_{N+2Z}_{_{c}}_{-K-1}]^{T} could be generated such that

$$H \times [ \begin{matrix}c \\ w\end{matrix} ] = 0 ,$$

where c=[c₀, c₁, c₂, . . . , c_{K-1}]^{T}; 0 is a column vector of all elements equal to 0. The encoding is performed in GF(2).

In some cases, in the general structure of natural message-passing iterative decoding algorithms, messages are exchanged between the variable and check nodes in discrete time steps. Initially, each variable node vⱼ 1≤j≤n, has an associated received value rⱼ, which is a random variable taking values in the channel output alphabet Y. Based on this, each variable sends a message belong to some message alphabet M. A common choice for this initial message is simply the received value rⱼ, or perhaps some quantized version of rⱼ for continuous output channels such as binary input additive white Gaussian noise (BIAWGN).

In some cases, each check node c processes the messages it receives from its neighbors and sends back a suitable message in M to each of its neighboring variable nodes. Upon receipt of the messages from the check nodes, each variable node vⱼ uses these together with its own received value rⱼ to produce new messages that are sent to its neighboring check nodes. This process continues for many time steps, till a certain cap on the number of iterations is reached. In the analysis, we are interested in the probability of incorrect decoding, such as the bit-error probability. For every time step i, i∈ [symbol] , the i'th iteration consists of a round check-to-variable node messages, followed by the variable nodes responding with their messages to the check nodes. The 0'th iteration consists of dummy messages from the check nodes, followed by the variable nodes sending their received values to the check nodes.

In some cases, an important condition in the determination of the next message based on the messages received from the neighbors is that message sent by u along an edge e does not depend on the message just received along edge e. This is important so that only “extrinsic” information is passed along from a node to its neighbor in each step. It is exactly this restriction that leads to the independence condition that makes analysis of the decoding possible.

In certain cases, an LDPC code is a new type of error correction code. Its performance in a mobile channel is improved compared with turbo code. Even without an interleaver, the error correction ability of an irregular LDPC code is better than turbo code. Therefore, the LDPC code was adopted in 5G communications. In addition, the simulation results show that LDPC has good performance in all block lengths and code rates, and the complexity is relatively low.

In the latest 5G standard, for example, the construction, coding, and interleaving scheme of parity matrix H of LDPC code is specified. In 5G standard, QC-LDPC code is adopted. QC-LDPC code belongs to a structured irregular LDPC code, which is composed of basic matrix H_{b} and lifting factor Z. In 5G standard, two basic matrices (i.e., BG1 and BG2) are determined. The basic matrices have eight basic matrices, respectively, and they have different dimensions. The corresponding basic matrix is selected according to the size and code rate of a transmission block. After the basic matrix is determined, the lifting factor is selected, and then, the basic matrix is modified according to the lifting factor to get the modified parity matrix H. Finally, according to the check matrix H, the encoded code word is directly obtained.

In essence, the interleaver is a device that can change the information distribution structure without changing the information content. It is employed to make the burst errors generated in the process of channel transmission decentralized. The LDPC code interleaving scheme adopted in 5G standard is bit interleaving with block interleaver. The interleaving method is to read the input sequence into a matrix by rows and then read out by columns. The process of deinterleaving is the opposite operation, i.e., read the interleaved sequence into the matrix by columns and then read it out by rows. The matrix is determined by the length and interleaving depth of the input sequence. The number of rows in the matrix is the interleaving depth, and the number of columns is the length of the input sequence divided by the interleaving depth. The interleaving depth is related to the modulation order. There are five modulation schemes specified in 5G NR standard, i.e., BPSK (binary phase shift keying), QPSK (quadrature phase shift keying), 16QAM (quadrature amplitude modulation), 64QAM, and 256QAM. The corresponding modulation orders are 1, 2, 4, 6, and 8, respectively. For example, if 16QAM modulation is used and the input sequence length is 8000 symbols, then the matrix size is 4×2000.

In some cases, due to its low complexity of encoding and decoding, the polar code has become a research hotspot of error correction code. The core of polar code construction is related to the channel polarization. In the process of coding, each subchannel is made to show a different reliability. When the length of information code to be transmitted continues to increase, some channels tend to the perfect channel with capacity close to 1 (error-free code), and the other channels tend to the pure noise channel with capacity close to 0. On this basis, we can select those channels whose capacity is close to 1 to transmit information directly to approximate the channel capacity. In addition, the polar code is the only coding scheme that can be strictly proved to achieve the Shannon limit.

The construction of the polar code is composed of error detection, code matrix generation, sequence, rate matching, and interleaving. The interleaving part can be divided into two steps, interleaving before coding, and interleaving after coding. Interleaving before coding is applicable to 5G-NR DCI (downlink control information), and there is no upstream interleaving; the interleaving after coding is applicable to 5G-NR UCI (uplink control information), and there is no downstream interleaving.

In certain cases, interleaving is performed to disrupt the information structure without changing the information content and reduce the relevance between information bits to improve the resistance to burst interference. In the interleaving of UCI, the right triangle interleaving method is specified. In this method, it is assumed that the storage unit is an isosceles right triangle with a right-angle side length of P, and the side length P is clearly defined in 3GPP, that is

$$P \times \frac{P}{2} \leq 8192.$$

Before information can be transmitted using a digital modulation scheme, the information bits are mapped to the constellation. Each point in the constellation is known as a symbol, making the full collection of symbols a kind of alphabet of the modulation scheme. For most digital modulation schemes, each symbol carries more than one bit. This implies that a (fixed) number of information bits must be “assigned” to each symbol in a process called mapping.

For BPSK, this baseband signal is simply a series of complex values taken from the set {1,−1}{1,−1}. These complex values are the symbols of BPSK. In some cases, the set {i,−i}{i,−i} can be used for BPSK. This is equivalent since it is just a rotation of the constellation by 90 degrees. However, typically {1,−1}{1,−1} is used (although it must be said that using {i,−i}{i,−i} makes it easier to not forget that the signal should always be treated as complex in this context, even though the values happen to be real).

The binary numeral system is ordered in the reflected binary code, also known as the Gray code, so that two subsequent values only differ in one bit (binary digit). In the typical sequence of binary numbers produced by the hardware that could provide an error or ambiguity during the change from one number to the next, gray codes are helpful. Because the first (n/2) values compare with the last (n/2) values in reverse order, gray code is also known as reflected binary code.

In one case, a gray code may include a single bit change where the gray code only allows for one bit to change when changing from one value to another. Because there is less ambiguity when changing values, this feature lessens the possibility of errors and glitches in digital systems.

In another case, a gray code may include a reflection property, which is a straightforward way for creating the Gray Code sequence that entails reflecting the current sequence before prefixing the new sequence with a new bit. For instance, start with a 2-bit Gray Code sequence and reflect it to make a 3-bit Gray Code sequence. The single-bit change property is upheld by the reflection property, which also makes sure the sequence is cyclic.

In some cases there are various types of gray codes, including:

Binary Reflected Gray Code: The most typical kind of Gray code utilized in digital systems is the binary reflected Gray code, also referred to as the reflected Gray code. Each succeeding number in this code differs from the one before it by a single bit. The binary code for each number is mirrored before being transformed into the Gray code, which is how the code gets its name.

Balanced Gray Code: Transition counts have equal in balanced Gray code. it is a unique variety of gray code in which every potential value appears exactly once in the sequence. A good example of where this kind of Gray coding is important in analog-to-digital converters.

N-ary Gray Code: This Gray code consist non-Boolean values like sequences of 1, 2, 3.

Two dimensional Gray code: This kind of Gray code is helpful in error correction.

Sequential Gray Code: Every number in the sequence is either the predecessor or the successor of the one before it. Certain applications, including robotics and manufacturing procedures, use this kind of Gray code.

The solution herein describes various embodiments of mechanisms and procedures to enhance LDPC error correction capabilities in interleaved LDPC-coded modulations where super-QAM modulations are used e.g., 1024-QAM and 4096-QAM. The solution includes the design of a channel interleaver that enables the re-ordering of the LDPC coded bits such that the encoded bits (variable nodes) associated with high degrees are mapped to most significant symbols' bits (MSBs) and encoded bits associated with low degrees are mapped to least significant symbols' bits (LSBs).

As used herein, the degree of an encoded bit may refer to the number of possible states or values that a bit can represent within a specific encoding scheme. As it relates to LDPC codes, the degree of an encoded bit (or variable node) is the number of parity-check equations it participates in. In other words, the degree of an LDPC node may refer to the number of connections to the node in a Tanner graph where a high degree node has a larger number of connections (edges) in a Tanner graph than other nodes (e.g., a number of connections that is greater than or equal to a threshold) and a low degree node has fewer connections in a Tanner graph than other nodes (e.g., a number of connections that is less than or equal to a threshold). Typically, bits have different degrees, with some low-degree nodes (faster to decode) and some high-degree nodes (stronger error correction). A higher degree typically provides better error correction. In one embodiment, the degree of a bit varies based on the irregularity of the LDPC parity-check matrix.

The irregular LDPC encoded bits degree distribution could be determined using several mechanisms such as density evolution (DE), extrinsic information transfer (EXIT) charts and alternatively protograph-based EXIT (PEXIT) charts. This bit re-ordering mechanism enables higher protection for LDPC coded bit (variable nodes) that impact the iterative decoder extrinsic information computations. As used herein, the degree distribution for LDPC codes may refer to how many variable nodes (bits) and check nodes (parity checks) have specific connection counts in the Tanner graph representation of the code.

The degrees of the check and the variable nodes affect the convergence behavior of the iterative decoder and thus affect the performance of the code. In general, the larger the variable node degrees, the higher the average reliabilities after decoding. Consequently, the error correction capability of LDPC codes is enhanced and even in scenarios where fading channels impact the detection of the super-QAM constellation symbols, the enhanced correction capabilities of the LDPC decoder could be leveraged to enable a correct decoding of the received codeword. At the receiver, the demodulator outputs are log-likelihood ratios (LLRs) or other extrinsic information, that are provided to the soft-input decoder.

A gray bit-to-symbols mapping is also described in this solution to enable targeted performances. The transmitting chain at the transmitter may include a forward error correction (FEC) encoder, an interleaver, a Gray bit-to-symbol mapper, and a super-QAM modulation block.

According to the first embodiment, the encoded LDPC bits could be fed to an interleaver that re-orders the bits such that the encoded LDPC bits with highest variable node degrees are mapped to the MSBs of one or more constellation symbols e.g., 256-QAM, 1024-QAM or 4096-QAM. On the other hand, the encoded LDPC bits with the lowest variable node degrees are mapped to the LSBs of one or more constellation symbols. This enables the high degree variable nodes to be correctly detected at the receiver even in time-varying and frequency-selective channel conditions, which ensures error detection and correction of the channel code. In this case, interleaved LDPC-coded modulation could compensate for reduced minimum squared Euclidean distance (MSED) of super-QAM constellations and therefore enable good performance by leveraging the error correction capabilities of the forward error correction code.

In one embodiment, the interleaver could re-order incoming encoded LDPC bits based on the degree distributions of the code. In this case, the interleaver might have prior knowledge about degree distribution of the irregular LDPC code and might associate encoded bit b₁ having node degree d₁ and encoded bit b₂ having node degree d₂ where d₁ is larger than d₂ with most significant bit l₁ and least significant bit l₂ of the same constellation symbol s₁ or alternatively associate b₁ with most significant bit l₁ of constellation symbol s₁ and b₂ with least significant bit l₂ of constellation symbol s₂ where s₁ and s₂ can be symbols of the same quadrant. In this case, each LDPC encoded bit or variable node could be associated with a node degree that characterizes its connectivity within the Tanner graph and thus quantifies its impact on the reliabilities of the iterative decoder's output. In this case, the degree distribution [symbol] _{LDPC} of LDPC code could be pre-configured, for example, in standards or signaled to the interleaver.

Additionally, in one embodiment, the interleaver may have prior knowledge about the modulation order M as well as the MSBs and LSBs associated with the constellation symbols. Higher order modulation schemes may be used to transmit multiple bits within a single modulation symbol. For example, quadrature phase shift keying (QPSK) and QAM transmit multiple bits per symbol. LTE utilizes 16-QAM, which transmits 4 bits per symbol and 64-QAM, which transmits 6 bits per symbol. 5G (NR) may allow use of 256-QAM (8 bits), 512-QAM (9 bits), or even higher orders. Although QAM modulation schemes are described as examples, the techniques disclosed herein may be used with other higher order modulation schemes. In such higher order modulation schemes, the probability that the MSB is changed due to interference is significantly lower than the probability that the LSB is changed due to interference. For example, as long as the receiver detects the correct quadrant for the symbol, the MSB may be correct, even if the LSB has been changed due to interference.

In an alternate embodiment, the interleaver might assign bits associated with higher degrees variable nodes (i.e., higher reliability ones) with LSBs, or a set of LSBs (in Gray coded modulations), and bits associated with lower degrees variable nodes (i.e., lower reliability ones) with MSBs, or a set of MSBs (in Gray coded modulations). Essentially, from a decoding perspective it is intuitive to map reliable bits to symbols that are adjacent, and “not so reliable” bits to symbols that are far apart (e.g., different quadrants).

In different embodiments, the variable nodes' degrees could be determined, pre-configured or signaled by the network entity to the UE. The computation of the VN (variable nodes) degrees could be performed using DE analysis, EXIT charts, PEXIT charts or the like.

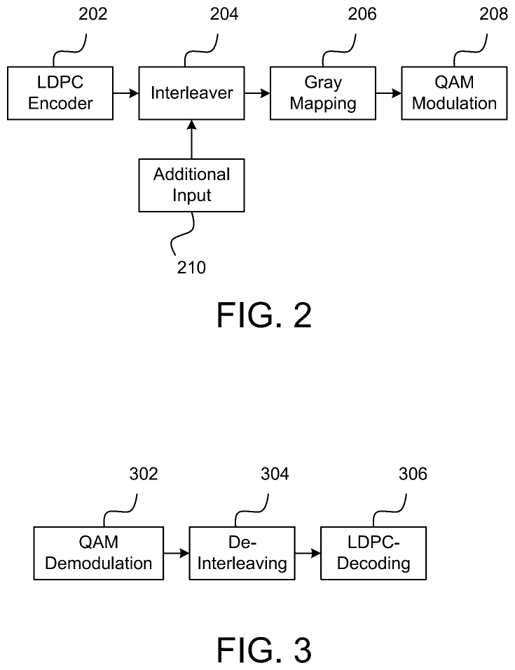

FIG. 2 illustrates an example transmission chain of interleaved LDPC-coded modulation, in accordance with aspects of the present disclosure. In other embodiments, the LDPC encoder 202 could be followed by an interleaver 204, as described above, and the output of the interleaver may be mapped according to a Gray mapping 206 into QAM symbols by QAM modulation 208. In this case, two adjacent QAM symbols are different in exactly one bit. Gray mapping 206 ensures that the symbol detected at the receiver would have a minimum number of erroneous bits. In this case, in worst cases where the LDPC encoded bits benefiting from higher protection by being mapped to the symbols' MSBs are being corrupted, the decoder could still succeed in decoding the received codeword. This mapping guarantees that the error correction capability threshold of the LDPC code is not surpassed and that even in cases of erroneous symbols' detection, the channel code could still correctly decode the received signal. In certain embodiments, additional input 210 may be provided to the interleaver 204 such as the degrees of the variable nodes.

In a second embodiment, the high degrees' LDPC encoded bits could be mapped to bits located between the MSBs and the LSBs or to LSBs of the two or more modulation symbols. In various embodiments, the stream of LDPC encoded bits could be generated by the LDPC encoder in the order of variable nodes' degree. For example, the output of the LDPC encoder would be a stream of bits ordered from the highest degree bits to the lowest degree bits. In this case, the interleaver could, knowing only the modulation order, arrange incoming bits according to their degrees into most and least significant bits of the modulation symbols.

In other embodiments, the channel bit-interleaver block, e.g., as defined in TS 38.212, could be omitted since the interleaver design presented here introduces some randomness to the bit sequence which adds some resilience against burst errors. In other implementations, the proposed interleaver design could additionally include the bit interleaving patterns by mapping the LDPC encoded bits into symbols' MSBs and LSBs such that the row-column channel bit interleaving pattern is considered.

FIG. 3 illustrates an example receiver chain of interleaved LDPC-coded modulation, in accordance with aspects of the present disclosure. In the depicted embodiment, the received signals could be demodulated using QAM demodulation 302 and the output of the QAM demodulation 302 could be de-interleaved 304 using an inverse permutation π⁻¹ that re-arranges the demodulated symbols to their initial order to form the LDPC codewords that will be ultimately fed into an LDPC decoder. The output of the modulator are extrinsic information like likelihoods or LLRs that could be fed to the soft-input channel code decoder.

According to one embodiment, the interleaved LDPC-coded modulation parameters θ could be determined using a neural network (NN). The parameters may include the code rate, the modulation order, the LDPC encoded bits' degree distributions as well as symbols' MSBs and LSBs. In this case, the parameters of the interleaved LDPC-coded modulation scheme could be determined based on the estimation of the mutual information.

In this case, the mutual information could be defined as

$${arg max}_{θ} I ( X ; Y ) ,$$

where X is the stream of information bits at the input of the LDPC encoder and Y is the output of the LDPC decoder at the receiver side. Maximizing the mutual information between X and Y results in a better interleaved LDPC-coded modulation's parameters adaptation and high symbol detection and error correction capabilities of the FEC.

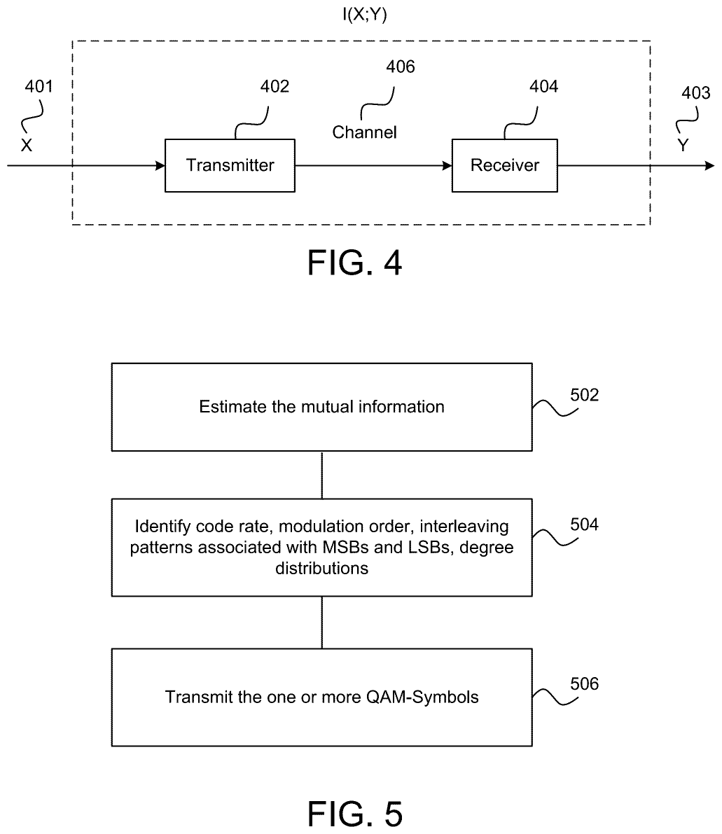

FIG. 4 illustrates an example of AI-assisted Interleaved coded modulation, in accordance with aspects of the present disclosure. In FIG. 4, inputs X 401, e.g., the stream of information bits, are provided to a transmitter 402, which includes the LDPC encoder, interleaver, Gray mapper, and QAM modulation. The transmitter 402 transmits the encoded bits over a channel 406 to a receiver 404, where the bits are demodulated, demapped, deinterleaved, and decoded to generate an output stream of LDPC decoded bits. The NN may be used to determine the LDPC-coded modulation parameters and/or to maximize the MI between X and Y.

In other embodiments, the NN could be trained to maximize the mutual information (MI) defined above or alternatively, the generalized mutual information (GMI), the Kullback-Leibler divergence (e.g., a statistical distance that measures how much a model probability distribution is different from a true probability), or alike metrics. In other implementations, the NN could be implemented to perform an accurate estimation of the mutual information. In this case, the interleaved LDPC-coded modulation parameters e.g., the code rate, modulation order, degree distributions, MSB and LSBs could be adaptively fine-tuned and adapted to the link between the transmitter and receiver according to the estimated MI or GMI. Once trained, the model may include a mapping that associates the signal to noise ratio (SNR)/SINR and CSI at transmitter (CSIT) values with the MI or alternatively the GMI.

FIG. 5 illustrates a flowchart of a method performed by a UE 600 or an NE 800 in accordance with aspects of the present disclosure. The operations of the method may be implemented by a UE 600 or an NE 800 as described herein. In some implementations, the UE 600 or the NE 800 may execute a set of instructions to control the function elements of the NE 800 to perform the described functions.

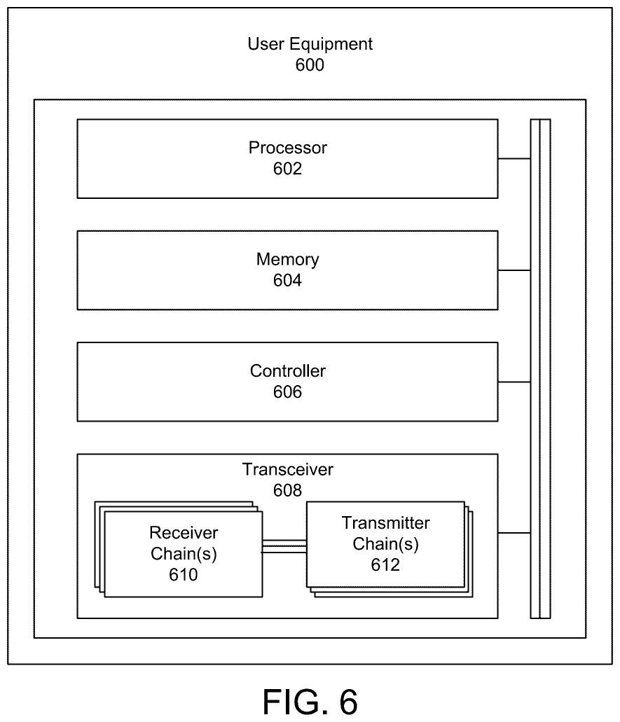

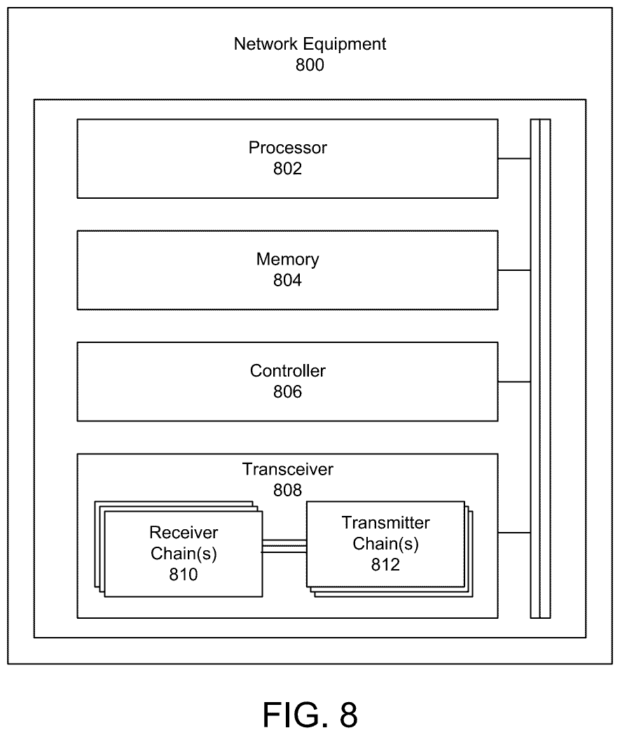

At step 502, the method may estimate the MI. The operations of step 502 may be performed in accordance with examples as described herein. In some implementations, aspects of the operations of step 502 may be performed by a UE 600, as described with reference to FIG. 6 or an NE 800, as described with reference to FIG. 8.

At step 504, the method may identify a code rate, modulation order, interleaving patterns associated with MSBs and LSBs, and/or degree distributions. The operations of step 504 may be performed in accordance with examples as described herein. In some implementations, aspects of the operations of step 504 may be performed by a UE 600, as described with reference to FIG. 6 or an NE 800, as described with reference to FIG. 8.

At step 506, the method may transmit the one or more QAM-Symbols. The operations of step 506 may be performed in accordance with examples as described herein. In some implementations, aspects of the operations of step 506 may be performed by a UE 600, as described with reference to FIG. 6 or an NE 800, as described with reference to FIG. 8.

It should be noted that the method described herein describes one possible implementation, and that the operations and the steps may be rearranged or otherwise modified and that other implementations are possible.

FIG. 6 illustrates an example of a UE 600 in accordance with aspects of the present disclosure. The UE 600 may include a processor 602, a memory 604, a controller 606, and a transceiver 608. The processor 602, the memory 604, the controller 606, or the transceiver 608, or various combinations thereof or various components thereof may be examples of means for performing various aspects of the present disclosure as described herein. These components may be coupled (e.g., operatively, communicatively, functionally, electronically, electrically) via one or more interfaces.

The processor 602, the memory 604, the controller 606, or the transceiver 608, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 602 may include an intelligent hardware device (e.g., a general-purpose processor, a DSP, a central processing unit (CPU), an ASIC, a field programmable gate array (FPGA), or any combination thereof). In some implementations, the processor 602 may be configured to operate the memory 604. In some other implementations, the memory 604 may be integrated into the processor 602. The processor 602 may be configured to execute computer-readable instructions stored in the memory 604 to cause the UE 600 to perform various functions of the present disclosure.

The memory 604 may include volatile or non-volatile memory. The memory 604 may store computer-readable, computer-executable code including instructions that, when executed by the processor 602, cause the UE 600 to perform various functions described herein. The code may be stored in a non-transitory computer-readable medium such the memory 604 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 602 and the memory 604 coupled with the processor 602 may be configured to cause the UE 600 to perform one or more of the UE functions described herein (e.g., executing, by the processor 602, instructions stored in the memory 604). Accordingly, the processor 602 may support wireless communication at the UE 600 in accordance with examples as disclosed herein.

In one embodiment, the UE 600 is configured to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled QAM on the stream of re-ordered encoded bits to generate one or more modulation symbols, and transmit the one or more modulation symbols.

In one embodiment, the UE 600 is configured to determine the degree of each of the encoded bits. In one embodiment, the UE 600 is configured to arrange the encoded bits using an interleaver, and wherein the interleaver is configured with a degree distribution of the LDPC code and a modulation format.

In one embodiment, the UE 600 is configured to determine the degree distribution of the LDPC code based on density evolution, extrinsic information transfer charts, photograph-based extrinsic information transfer charts, or a combination thereof.

In one embodiment, the most significant bits and the least significant bits of the one or more constellation symbols are updated based on channel conditions, interference, or a combination thereof. In one embodiment, the encoded bits are part of one or more codewords and wherein the encoded bits are ordered, at output of an LDPC encoder, within the one or more codewords based on the degree of each of the encoded bits.

In one embodiment, the UE 600 is configured to associate the encoded bits with the most significant bits or the least significant bits of one or more constellation symbols based on the degree of each of the encoded bits. In one embodiment, the UE 600 is configured to determine transmission chain parameters using a neural network.

In one embodiment, the transmission chain parameters comprise a code rate, a modulation order, a degree distribution for the encoded bits, most significant bits of one or more constellation symbols, least significant bits of one or more constellation symbols, or a combination thereof.

In one embodiment, the UE 600 is configured to detect one or more constellation symbols associated with a stream of LDPC encoded bits, demodulate the one or more constellation symbols to generate one or more log-likelihood ratios, and decode the encoded bits by providing the log-likelihood ratios to an LDPC decoder to generate a stream of decoded bits.

In one embodiment, the UE 600 is configured to prioritize one or more most significant bits of the one or more constellation symbols to reduce a number of iterations of the LDPC decoder. In one embodiment, the UE 600 is configured to configure the transmission chain parameters using a neural network, and wherein the LDPC parameters comprise a code rate, a modulation order, a degree distribution for the encoded bits, most significant bits of one or more constellation symbols, least significant bits of one or more constellation symbols, or a combination thereof.

In one embodiment, the UE 600 is configured to maximize mutual information of signals at an input of an LDPC encoder and signals at an output of the LDPC decoder or minimize a Kullback-Leibler divergence of the signals at the input of the LDPC encoder and the signals at the output of the LDPC decoder. In one embodiment, the mutual information is further determined based on one or more extrinsic information transfer charts of LDPC codes.

The controller 606 may manage input and output signals for the UE 600. The controller 606 may also manage peripherals not integrated into the UE 600. In some implementations, the controller 606 may utilize an operating system (OS) such as iOS®, ANDROID®, WINDOWS®, or other operating systems. In some implementations, the controller 606 may be implemented as part of the processor 602.

In some implementations, the UE 600 may include at least one transceiver 608. In some other implementations, the UE 600 may have more than one transceiver 608. The transceiver 608 may represent a wireless transceiver. The transceiver 608 may include one or more receiver chains 610, one or more transmitter chains 612, or a combination thereof.

A receiver chain 610 may be configured to receive signals (e.g., control information, data, packets) over a wireless medium. For example, the receiver chain 610 may include one or more antennas for receiving the signal over the air or wireless medium. The receiver chain 610 may include at least one amplifier (e.g., a low-noise amplifier (LNA)) configured to amplify the received signal. The receiver chain 610 may include at least one demodulator configured to demodulate the received signal and obtain the transmitted data by reversing the modulation technique applied during transmission of the signal. The receiver chain 610 may include at least one decoder for decoding/processing the demodulated signal to receive the transmitted data.

A transmitter chain 612 may be configured to generate and transmit signals (e.g., control information, data, packets). The transmitter chain 612 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 612 may also include at least one power amplifier configured to amplify the modulated signal to an appropriate power level suitable for transmission over the wireless medium. The transmitter chain 612 may also include one or more antennas for transmitting the amplified signal into the air or wireless medium.

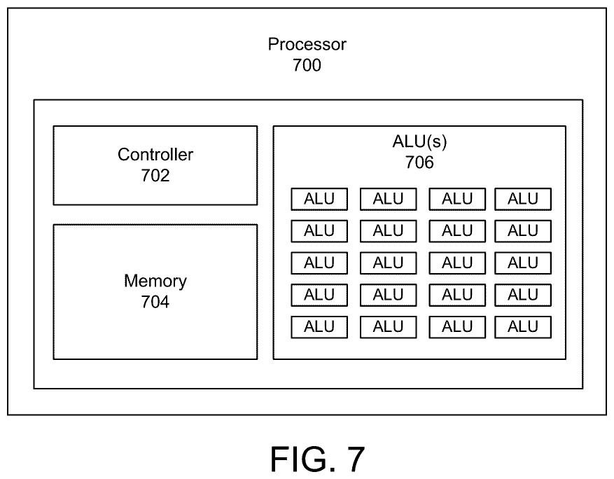

FIG. 7 illustrates an example of a processor 700 in accordance with aspects of the present disclosure. The processor 700 may be an example of a processor configured to perform various operations in accordance with examples as described herein. The processor 700 may include a controller 702 configured to perform various operations in accordance with examples as described herein. The processor 700 may optionally include at least one memory 704, which may be, for example, an L1/L2/L3 cache. Additionally, or alternatively, the processor 700 may optionally include one or more arithmetic-logic units (ALUs) 706. One or more of these components may be in electronic communication or otherwise coupled (e.g., operatively, communicatively, functionally, electronically, electrically) via one or more interfaces (e.g., buses).

The processor 700 may be a processor chipset and include a protocol stack (e.g., a software stack) executed by the processor chipset to perform various operations (e.g., receiving, obtaining, retrieving, transmitting, outputting, forwarding, storing, determining, identifying, accessing, writing, reading) in accordance with examples as described herein. The processor chipset may include one or more cores, one or more caches (e.g., memory local to or included in the processor chipset (e.g., the processor 700) or other memory (e.g., random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others).

The controller 702 may be configured to manage and coordinate various operations (e.g., signaling, receiving, obtaining, retrieving, transmitting, outputting, forwarding, storing, determining, identifying, accessing, writing, reading) of the processor 700 to cause the processor 700 to support various operations in accordance with examples as described herein. For example, the controller 702 may operate as a control unit of the processor 700, generating control signals that manage the operation of various components of the processor 700. These control signals include enabling or disabling functional units, selecting data paths, initiating memory access, and coordinating timing of operations.

The controller 702 may be configured to fetch (e.g., obtain, retrieve, receive) instructions from the memory 704 and determine subsequent instruction(s) to be executed to cause the processor 700 to support various operations in accordance with examples as described herein. The controller 702 may be configured to track memory address of instructions associated with the memory 704. The controller 702 may be configured to decode instructions to determine the operation to be performed and the operands involved. For example, the controller 702 may be configured to interpret the instruction and determine control signals to be output to other components of the processor 700 to cause the processor 700 to support various operations in accordance with examples as described herein. Additionally, or alternatively, the controller 702 may be configured to manage flow of data within the processor 700. The controller 702 may be configured to control transfer of data between registers, arithmetic logic units (ALUs), and other functional units of the processor 700.

The memory 704 may include one or more caches (e.g., memory local to or included in the processor 700 or other memory, such RAM, ROM, DRAM, SDRAM, SRAM, MRAM, flash memory, etc. In some implementations, the memory 704 may reside within or on a processor chipset (e.g., local to the processor 700). In some other implementations, the memory 704 may reside external to the processor chipset (e.g., remote to the processor 700).

The memory 704 may store computer-readable, computer-executable code including instructions that, when executed by the processor 700, cause the processor 700 to perform various functions described herein. The code may be stored in a non-transitory computer-readable medium such as system memory or another type of memory. The controller 702 and/or the processor 700 may be configured to execute computer-readable instructions stored in the memory 704 to cause the processor 700 to perform various functions. For example, the processor 700 and/or the controller 702 may be coupled with or to the memory 704, the processor 700, the controller 702, and the memory 704 may be configured to perform various functions described herein. In some examples, the processor 700 may include multiple processors and the memory 704 may include multiple memories. One or more of the multiple processors may be coupled with one or more of the multiple memories, which may, individually or collectively, be configured to perform various functions herein.

The one or more ALUs 706 may be configured to support various operations in accordance with examples as described herein. In some implementations, the one or more ALUs 706 may reside within or on a processor chipset (e.g., the processor 700). In some other implementations, the one or more ALUs 706 may reside external to the processor chipset (e.g., the processor 700). One or more ALUs 706 may perform one or more computations such as addition, subtraction, multiplication, and division on data. For example, one or more ALUs 706 may receive input operands and an operation code, which determines an operation to be executed. One or more ALUs 706 be configured with a variety of logical and arithmetic circuits, including adders, subtractors, shifters, and logic gates, to process and manipulate the data according to the operation. Additionally, or alternatively, the one or more ALUs 706 may support logical operations such as AND, OR, exclusive-OR (XOR), not-OR (NOR), and not-AND (NAND), enabling the one or more ALUs 706 to handle conditional operations, comparisons, and bitwise operations.

In various embodiments, the processor 700 may support wireless communication of a UE, in accordance with examples as disclosed herein. In other embodiments, the processor 700 may support wireless communication of a RAN entity, in accordance with examples as disclosed herein.

In one embodiment, the processor 700 is configured to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled QAM on the stream of re-ordered encoded bits to generate one or more modulation symbols, and transmit the one or more modulation symbols.

In one embodiment, the processor 700 is configured to determine the degree of each of the encoded bits. In one embodiment, the processor 700 is configured to arrange the encoded bits using an interleaver, and wherein the interleaver is configured with a degree distribution of the LDPC code and a modulation format.

In one embodiment, the processor 700 is configured to determine the degree distribution of the LDPC code based on density evolution, extrinsic information transfer charts, photograph-based extrinsic information transfer charts, or a combination thereof.

In one embodiment, the most significant bits and the least significant bits of the one or more constellation symbols are updated based on channel conditions, interference, or a combination thereof. In one embodiment, the encoded bits are part of one or more codewords and wherein the encoded bits are ordered, at output of an LDPC encoder, within the one or more codewords based on the degree of each of the encoded bits.

In one embodiment, the processor 700 is configured to associate the encoded bits with the most significant bits or the least significant bits of one or more constellation symbols based on the degree of each of the encoded bits. In one embodiment, the processor 700 is configured to determine transmission chain parameters using a neural network.

In one embodiment, the transmission chain parameters comprise a code rate, a modulation order, a degree distribution for the encoded bits, most significant bits of one or more constellation symbols, least significant bits of one or more constellation symbols, or a combination thereof.

In one embodiment, the processor 700 is configured to detect one or more constellation symbols associated with a stream of LDPC encoded bits, demodulate the one or more constellation symbols to generate one or more log-likelihood ratios, and decode the encoded bits by providing the log-likelihood ratios to an LDPC decoder to generate a stream of decoded bits.

In one embodiment, the processor 700 is configured to prioritize one or more most significant bits of the one or more constellation symbols to reduce a number of iterations of the LDPC decoder. In one embodiment, the processor 700 is configured to configure the transmission chain parameters using a neural network, and wherein the LDPC parameters comprise a code rate, a modulation order, a degree distribution for the encoded bits, most significant bits of one or more constellation symbols, least significant bits of one or more constellation symbols, or a combination thereof.

In one embodiment, the processor 700 is configured to maximize mutual information of signals at an input of an LDPC encoder and signals at an output of the LDPC decoder or minimize a Kullback-Leibler divergence of the signals at the input of the LDPC encoder and the signals at the output of the LDPC decoder. In one embodiment, the mutual information is further determined based on one or more extrinsic information transfer charts of LDPC codes.

FIG. 8 illustrates an example of a NE 800 in accordance with aspects of the present disclosure. The NE 800 may include a processor 802, a memory 804, a controller 806, and a transceiver 808. The processor 802, the memory 804, the controller 806, or the transceiver 808, or various combinations thereof or various components thereof may be examples of means for performing various aspects of the present disclosure as described herein. These components may be coupled (e.g., operatively, communicatively, functionally, electronically, electrically) via one or more interfaces.

The processor 802, the memory 804, the controller 806, or the transceiver 808, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 802 may include an intelligent hardware device (e.g., a general-purpose processor, a DSP, a CPU, an ASIC, an FPGA, or any combination thereof). In some implementations, the processor 802 may be configured to operate the memory 804. In some other implementations, the memory 804 may be integrated into the processor 802. The processor 802 may be configured to execute computer-readable instructions stored in the memory 804 to cause the NE 800 to perform various functions of the present disclosure.

The memory 804 may include volatile or non-volatile memory. The memory 804 may store computer-readable, computer-executable code including instructions when executed by the processor 802 cause the NE 800 to perform various functions described herein. The code may be stored in a non-transitory computer-readable medium such the memory 804 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 802 and the memory 804 coupled with the processor 802 may be configured to cause the NE 800 to perform one or more of the RAN functions described herein (e.g., executing, by the processor 802, instructions stored in the memory 804). For example, the processor 802 may support wireless communication at the NE 800 in accordance with examples as disclosed herein.

In one embodiment, the NE 800 is configured to encode data using a LDPC code to generate a stream of encoded bits, associate each encoded bit of the stream of encoded bits with most significant bits and least significant bits of one or more constellation symbols based on a degree of each of the encoded bits, generate a stream of re-ordered encoded bits, wherein a first set of encoded bits associated with the most significant bits have a higher degree than a second set of encoded bits associated with the least significant bits, perform Gray-Labeled QAM on the stream of re-ordered encoded bits to generate one or more modulation symbols, and transmit the one or more modulation symbols.

In one embodiment, the NE 800 is configured to determine the degree of each of the encoded bits. In one embodiment, the NE 800 is configured to arrange the encoded bits using an interleaver, and wherein the interleaver is configured with a degree distribution of the LDPC code and a modulation format.

In one embodiment, the NE 800 is configured to determine the degree distribution of the LDPC code based on density evolution, extrinsic information transfer charts, photograph-based extrinsic information transfer charts, or a combination thereof.

In one embodiment, the most significant bits and the least significant bits of the one or more constellation symbols are updated based on channel conditions, interference, or a combination thereof. In one embodiment, the encoded bits are part of one or more codewords and wherein the encoded bits are ordered, at output of an LDPC encoder, within the one or more codewords based on the degree of each of the encoded bits.

In one embodiment, the NE 800 is configured to associate the encoded bits with the most significant bits or the least significant bits of one or more constellation symbols based on the degree of each of the encoded bits. In one embodiment, the NE 800 is configured to determine transmission chain parameters using a neural network.

In one embodiment, the transmission chain parameters comprise a code rate, a modulation order, a degree distribution for the encoded bits, most significant bits of one or more constellation symbols, least significant bits of one or more constellation symbols, or a combination thereof.

In one embodiment, the NE 800 is configured to detect one or more constellation symbols associated with a stream of LDPC encoded bits, demodulate the one or more constellation symbols to generate one or more log-likelihood ratios, and decode the encoded bits by providing the log-likelihood ratios to an LDPC decoder to generate a stream of decoded bits.

In one embodiment, the NE 800 is configured to prioritize one or more most significant bits of the one or more constellation symbols to reduce a number of iterations of the LDPC decoder. In one embodiment, the NE 800 is configured to configure the transmission chain parameters using a neural network, and wherein the LDPC parameters comprise a code rate, a modulation order, a degree distribution for the encoded bits, most significant bits of one or more constellation symbols, least significant bits of one or more constellation symbols, or a combination thereof.

In one embodiment, the NE 800 is configured to maximize mutual information of signals at an input of an LDPC encoder and signals at an output of the LDPC decoder or minimize a Kullback-Leibler divergence of the signals at the input of the LDPC encoder and the signals at the output of the LDPC decoder. In one embodiment, the mutual information is further determined based on one or more extrinsic information transfer charts of LDPC codes.

The controller 806 may manage input and output signals for the NE 800. The controller 806 may also manage peripherals not integrated into the NE 800. In some implementations, the controller 806 may utilize an operating system such as iOS®, ANDROID®, WINDOWS®, or other operating systems. In some implementations, the controller 806 may be implemented as part of the processor 802.

In some implementations, the NE 800 may include at least one transceiver 808. In some other implementations, the NE 800 may have more than one transceiver 808. The transceiver 808 may represent a wireless transceiver. The transceiver 808 may include one or more receiver chains 810, one or more transmitter chains 812, or a combination thereof.

A receiver chain 810 may be configured to receive signals (e.g., control information, data, packets) over a wireless medium. For example, the receiver chain 810 may include one or more antennas for receiving the signal over the air or wireless medium. The receiver chain 810 may include at least one amplifier (e.g., a low-noise amplifier (LNA)) configured to amplify the received signal. The receiver chain 810 may include at least one demodulator configured to demodulate the received signal and obtain the transmitted data by reversing the modulation technique applied during transmission of the signal. The receiver chain 810 may include at least one decoder for decoding/processing the demodulated signal to receive the transmitted data.

A transmitter chain 812 may be configured to generate and transmit signals (e.g., control information, data, packets). The transmitter chain 812 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 812 may also include at least one power amplifier configured to amplify the modulated signal to an appropriate power level suitable for transmission over the wireless medium. The transmitter chain 812 may also include one or more antennas for transmitting the amplified signal into the air or wireless medium.

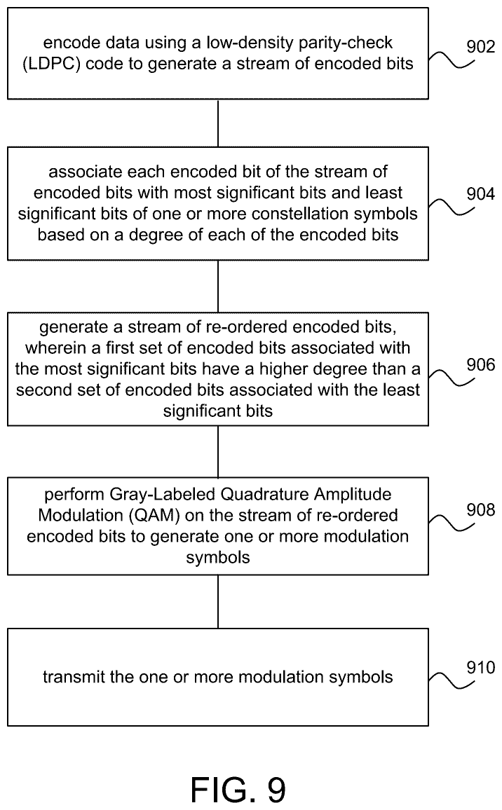

FIG. 9 illustrates a flowchart of a method performed by a UE 600 or an NE 800 in accordance with aspects of the present disclosure. The operations of the method may be implemented by a UE 600 or an NE 800 as described herein. In some implementations, the UE 600 or the NE 800 may execute a set of instructions to control the function elements of the UE 600 or the NE 800 to perform the described functions.

At step 902, the method may encode data using a LDPC code to generate a stream of encoded bits. The operations of step 902 may be performed in accordance with examples as described herein. In some implementations, aspects of the operations of step 902 may be performed by a UE 600, as described with reference to FIG. 6, or an NE 800, as described with reference to FIG. 8.

At step 904, the method may associate each encoded bit of the stream of encoded bits with most significant bits and least significant bits of one or more constellation symbols based on a degree of each of the encoded bits. The operations of step 904 may be performed in accordance with examples as described herein. In some implementations, aspects of the operations of step 904 may be performed by a UE 600, as described with reference to FIG. 6, or an NE 800, as described with reference to FIG. 8.

At step 906, the method may generate a stream of re-ordered encoded bits, wherein a first set of encoded bits associated with the most significant bits have a higher degree than a second set of encoded bits associated with the least significant bits. The operations of step 906 may be performed in accordance with examples as described herein. In some implementations, aspects of the operations of step 906 may be performed by a UE 600, as described with reference to FIG. 6, or an NE 800, as described with reference to FIG. 8.

At step 908, the method may perform Gray-Labeled QAM modulation on the stream of re-ordered encoded bits to generate one or more modulation symbols. The operations of step 908 may be performed in accordance with examples as described herein. In some implementations, aspects of the operations of step 908 may be performed by a UE 600, as described with reference to FIG. 6, or an NE 800, as described with reference to FIG. 8.

At step 910, the method may transmit the one or more modulation symbols. The operations of step 910 may be performed in accordance with examples as described herein. In some implementations, aspects of the operations of step 910 may be performed by a UE 600, as described with reference to FIG. 6, or an NE 800, as described with reference to FIG. 8.

It should be noted that the method described herein describes one possible implementation, and that the operations and the steps may be rearranged or otherwise modified and that other implementations are possible.

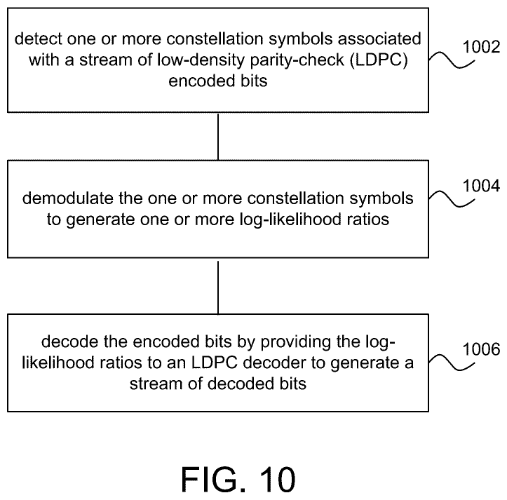

FIG. 10 illustrates a flowchart of a method performed by a UE 600 or an NE 800 in accordance with aspects of the present disclosure. The operations of the method may be implemented by a UE 600 or an NE 800 as described herein. In some implementations, the UE 600 or the NE 800 may execute a set of instructions to control the function elements of the UE 600 or the NE 800 to perform the described functions.

At step 1002, the method may detect one or more constellation symbols associated with a stream of LDPC encoded bits. The operations of step 1002 may be performed in accordance with examples as described herein. In some implementations, aspects of the operations of step 1002 may be performed by a UE 600, as described with reference to FIG. 6, or an NE 800, as described with reference to FIG. 8.

At step 1004, the method may demodulate the one or more constellation symbols to generate one or more log-likelihood ratios. The operations of step 1004 may be performed in accordance with examples as described herein. In some implementations, aspects of the operations of step 1004 may be performed by a UE 600, as described with reference to FIG. 6, or an NE 800, as described with reference to FIG. 8.

At step 1006, the method may decode the encoded bits by providing the log-likelihood ratios to an LDPC decoder to generate a stream of decoded bits. The operations of step 1006 may be performed in accordance with examples as described herein. In some implementations, aspects of the operations of step 1006 may be performed by a UE 600, as described with reference to FIG. 6, or an NE 800, as described with reference to FIG. 8.

It should be noted that the method described herein describes one possible implementation, and that the operations and the steps may be rearranged or otherwise modified and that other implementations are possible.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A network equipment (NE) for wireless communication, comprising:
at least one memory; and
at least one processor coupled with the at least one memory and configured to cause the NE to:
encode data using a low-density parity-check (LDPC) code to generate a stream of encoded bits;
associate each encoded bit of the stream of encoded bits with most significant bits and least significant bits of one or more constellation symbols based on a degree of each of the encoded bits;
generate a stream of re-ordered encoded bits, wherein a first set of encoded bits associated with the most significant bits have a higher degree than a second set of encoded bits associated with the least significant bits;
perform Gray-Labeled Quadrature Amplitude Modulation (QAM) on the stream of re-ordered encoded bits to generate one or more modulation symbols; and
transmit the one or more modulation symbols.

2. The NE of claim 1, wherein the at least one processor is configured to cause the NE to determine the degree of each of the encoded bits.

3. The NE of claim 1, wherein the at least one processor is configured to cause the NE to arrange the encoded bits using an interleaver, and wherein the interleaver is configured with a degree distribution of the LDPC code and a modulation format.

4. The NE of claim 3, wherein the at least one processor is configured to cause the NE to determine the degree distribution of the LDPC code based on density evolution, extrinsic information transfer charts, photograph-based extrinsic information transfer charts, or a combination thereof.

5. The NE of claim 4, wherein the most significant bits and the least significant bits of the one or more constellation symbols are updated based on channel conditions, interference, or a combination thereof.

6. The NE of claim 3, wherein the encoded bits are part of one or more codewords and wherein the encoded bits are ordered, at output of an LDPC encoder, within the one or more codewords based on the degree of each of the encoded bits.

7. The NE of claim 6, wherein the at least one processor is configured to cause the NE to associate the encoded bits with the most significant bits or the least significant bits of one or more constellation symbols based on the degree of each of the encoded bits.

8. The NE of claim 1, wherein the at least one processor is configured to cause the NE to determine transmission chain parameters using a neural network.

9. The NE of claim 8, wherein the transmission chain parameters comprise a code rate, a modulation order, a degree distribution for the encoded bits, most significant bits of one or more constellation symbols, least significant bits of one or more constellation symbols, or a combination thereof.

10. A method performed by a network equipment (NE), the method comprising:
encoding data using a low-density parity-check (LDPC) code to generate a stream of encoded bits;
associating each encoded bit of the stream of encoded bits with most significant bits and least significant bits of one or more constellation symbols based on a degree of each of the encoded bits;
generating a stream of re-ordered encoded bits, wherein a first set of encoded bits associated with the most significant bits have a higher degree than a second set of encoded bits associated with the least significant bits;
performing Gray-Labeled Quadrature Amplitude Modulation (QAM) on the stream of re-ordered encoded bits to generate one or more modulation symbols; and
transmitting the one or more modulation symbols.

11. The method of claim 10, further comprising determining the degree of each of the encoded bits.

12. The method of claim 10, further comprising arranging the encoded bits using an interleaver, wherein the interleaver is configured with a degree distribution of the LDPC code and a modulation format.

13. The method of claim 12, further comprising determining the degree distribution of the LDPC code based on density evolution, extrinsic information transfer charts, photograph-based extrinsic information transfer charts, or a combination thereof.

14. The method of claim 12, wherein the encoded bits are part of one or more codewords and wherein the encoded bits are ordered, at output of an LDPC encoder, within the one or more codewords based on the degree of each of the encoded bits.

15. A network equipment (NE) for wireless communication, comprising:
at least one memory; and
at least one processor coupled with the at least one memory and configured to cause the NE to:
detect one or more constellation symbols associated with a stream of low-density parity-check (LDPC) encoded bits;
demodulate the one or more constellation symbols to generate one or more log-likelihood ratios; and
decode the encoded bits by providing the log-likelihood ratios to an LDPC decoder to generate a stream of decoded bits.

16. The NE of claim 15, wherein the at least one processor is configured to cause the NE to prioritize one or more most significant bits of the one or more constellation symbols to reduce a number of iterations of the LDPC decoder.

17. The NE of claim 15, wherein the at least one processor is configured to cause the NE to configure transmission chain parameters using a neural network, and wherein the transmission chain parameters comprise a code rate, a modulation order, a degree distribution for the encoded bits, most significant bits of one or more constellation symbols, least significant bits of one or more constellation symbols, or a combination thereof.

18. The NE of claim 15, wherein the at least one processor is configured to cause the NE to maximize mutual information of signals at an input of an LDPC encoder and signals at an output of the LDPC decoder or minimize a Kullback-Leibler divergence of the signals at the input of the LDPC encoder and the signals at the output of the LDPC decoder.

19. The NE of claim 18, wherein the mutual information is further determined based on one or more extrinsic information transfer charts of LDPC codes.

20. A method performed by a network equipment (NE), the method comprising:
detecting one or more constellation symbols associated with a stream of low-density parity-check (LDPC) encoded bits;
demodulating the one or more constellation symbols to generate one or more log-likelihood ratios; and
decoding the encoded bits by providing the log-likelihood ratios to an LDPC decoder to generate a stream of decoded bits.
